(19) United States
(12) Patent Application Publication
(10) Pub. No.: US 2012/0318619 A1
(43) Pub. Date: Dec. 20, 2012

(54) REMOTE SAFETY BRAKE

(76) Inventors: Charles L. Cooper, II, Indianapolis, IN (US); Joshua TN Lambert, Greenwood, IN (US)

(21) Appl. No.: 13/161,489

(22) Filed: Jun. 15, 2011

(51) Int. Cl. B62L 3/00; F16D 65/30; H05K 13/00; B60T 7/02

(52) U.S. Cl. 188/24.11; 188/158; 29/592.1

(57) ABSTRACT

In an embodiment of the invention, an apparatus includes: a remote safety brake including a transmitter configured to transmit a control signal, a receiver configured to receive the control signal, and a brake control stage coupled to the receiver. The brake control stage is responsive to the control signal, and the transmitter is remotely disposed away from the receiver and is remotely disposed away from the brake control stage.

### TECHNICAL FIELD

Embodiments of the invention relate generally to a remote safety brake.

### BACKGROUND

Manually operated brakes in bicycles are well known to those skilled in the art. Bicycles are manufactured and are commercially-available in various forms such as, for example and without limitations, two-wheeled bicycles, tricycles for children, three-wheeled manually-powered bicycles, double-seated bicycles, sport racing bicycles, manually-powered dirt bicycles, or/and other embodiments of bicycles. The bicycle rider uses a pivotally-operated lever that is typically coupled to the bicycle handle-bar, in order to move a brake pad into contact with the bicycle wheel so that the brake can decrease the speed of or stop the moving bicycle.

Since bicycles (including tricycles and other bicycle embodiments mentioned above) are commonly used by children, there is a continuing need to increase the safety and protection of children who are riding bicycles. For example, when a parent (or another individual or supervising adult) is watching his/her child who is riding a bicycle, it would be desirable for the parent to have the capability to remotely stop the bicycle or to remotely decrease the speed of the bicycle. This remote capability would allow the parent to remotely prevent the child from riding the bicycle at a far distance from the parent's physical location and to also remotely stop or slow down the bicycle so that the bicycle does not collide with another object that is moving (e.g., a person, another bicycle, or a moving car) or is stationary (e.g., a tree, a wall, or a parked car).

Therefore, the current technology is limited in its capabilities and does not sufficiently provide for the adequate safety of a child who is using a bicycle.

### SUMMARY

In one embodiment of the invention, an apparatus includes: a remote safety brake including a transmitter configured to transmit a control signal, a receiver configured to receive the control signal, and a brake control stage coupled to the receiver. The brake control stage is responsive to the control signal, and the transmitter is remotely disposed away from the receiver and is remotely disposed away from the brake control stage.

In another embodiment of the invention, an apparatus includes: a remote safety brake including means for transmitting a control signal, means for receiving the control signal, and means for controlling a brake, wherein the controlling means is coupled to the receiving means. The controlling means is responsive to the control signal, and the transmitting means is remotely disposed away from the receiving means and is remotely disposed away from the controlling means.

In yet another embodiment of the invention, a method includes: transmitting a control signal, receiving the control signal, and in response to the control signal, controlling a brake.

In yet another embodiment of the invention, a method of assembling a remote safety brake includes: providing a transmitter configured to transmit a control signal, providing a receiver configured to receive the control signal, providing a brake control stage, and attaching the brake control stage to the receiver. The brake control stage is responsive to the control signal, and the transmitter is remotely disposed away from the receiver and is remotely disposed away from the brake control stage.

It is to be understood that both the foregoing general description and the following detailed description are exemplary and explanatory only and are not restrictive of the invention, as claimed.

The accompanying drawings, which are incorporated in and constitute a part of this specification, illustrate one (several) embodiment(s) of the invention and together with the description, serve to explain the principles of the invention.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 is a block diagram of an apparatus for a remote safety brake, in accordance with an embodiment of the invention.

FIG. 2 is a block diagram showing additional details of the apparatus of FIG. 1, in accordance with an embodiment of the invention.

FIGS. 3a, 3b, and 3c are block diagrams of various positions of a slidable actuator in the brake control stage, in accordance with an embodiment of the invention.

FIG. 4 is a block diagram of signals with different duty cycles that can vary the speed of closing the brake, in accordance with an embodiment of the invention.

FIG. 5 is a flow diagram of a method in accordance with an embodiment of the invention.

### DETAILED DESCRIPTION OF PREFERRED EMBODIMENTS

In the description herein, numerous specific details are provided, such as examples of components, parts, structures, and/or methods, to provide a thorough understanding of embodiments of the invention. One skilled in the relevant art will recognize, however, that an embodiment of the invention can be practiced without one or more of the specific details, or with other apparatus, systems, methods, components, materials, parts, structures, and/or the like. In other instances, well-known structures, materials, or operations are not shown or described in detail to avoid obscuring aspects of embodiments of the invention. Additionally, the drawings are representative in nature and their shapes are not intended to illustrate the precise shape or precise size of any element and are not intended to limit the scope of the invention.

Those skilled in the art will understand that when an element or part in the drawings is referred to as being “on” (or “connected” to or “coupled” to or “attached” to) another element, it can be directly on (or attached to) the other element or intervening elements may also be present. Furthermore, relative terms such as “inner”, “outer”, “upper”, “above”, “lower”, “beneath”, and “below”, and similar terms, may be used herein to describe a relationship of one element or another element. It is understood that these terms are intended to encompass different orientations of the device in addition to the orientation depicted in the drawings. Additionally, as used herein, the terms “and/or” or “or/and” include any and all combination of one or more of the associated listed items.

Although the terms first, second, and the like may be used herein to describe various elements, components, parts, regions, layers and/or sections, these elements, components, parts, regions, layers, chambers, and/or sections should not be limited by these terms. These terms are only used to distinguish one element, component, part, region, layer, chamber, or section from another element, component, part, region, layer, chamber, or section. Thus, a first element, component, part, region, layer, chamber, or section discussed below could be termed a second element, component, part region, layer, chamber, or section without departing from the teachings of the present invention.

Embodiments of the invention are described herein with reference to cross-sectional view illustrations that are schematic illustrations of representative embodiments of the invention. As such, variations from the shapes of the illustrations as a result of, for example, manufacturing techniques and/or tolerances are expected. Embodiments of the invention should not be construed as limited to the particular shapes of the regions or components (or parts or elements) illustrated herein but are to include deviations in shapes that result, for example, from manufacturing or particular implementations. For example, an element illustrated or described as square or rectangular may typically have rounded or curved features due to normal manufacturing tolerances or due to a particular implementation. Thus, the elements illustrated in the drawings are schematic in nature and their shapes are not intended to illustrate the precise shape of an element of a device and are not intended to limit the scope of the invention.

Based on the discussion of the embodiments of the invention as presented herein, those skilled in the art will realize that the positions and/or configurations of the components in the drawings can be varied in different sizes, different shapes, different positions, and/or different configurations. Therefore, various components shown in the drawings can be placed in other positions that differ from the configuration as shown in the drawings. The components in the drawings are illustrated in non-limiting example positions for purposes of explaining the functionalities of the embodiments of the invention, and these components in the drawings can be configured into other example positions.

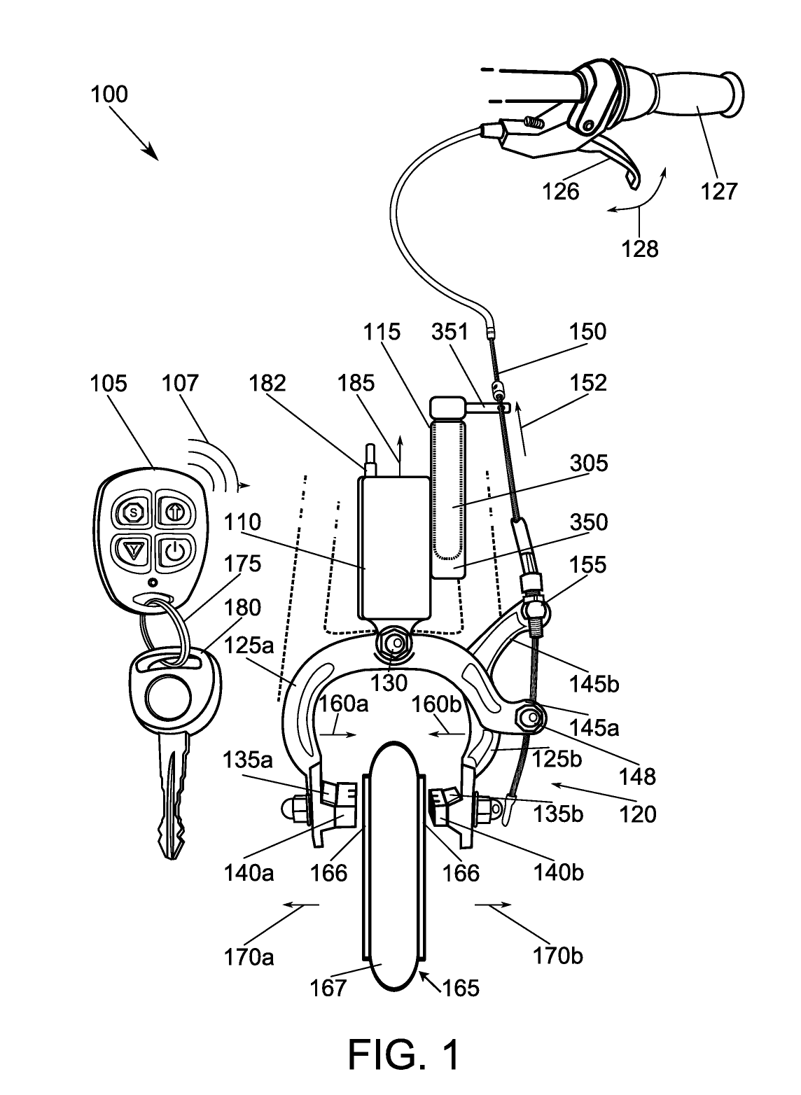

FIG. 1 is a block diagram of an apparatus 100 for a remote safety brake, in accordance with an embodiment of the invention. The apparatus 100 (remote safety brake system 100) includes a transmitter 105 (transmitter device 105) for transmitting one or more control signals 107, a receiver 110 (receiver device 110), and a brake control stage 115 that is coupled to the receiver 110. The transmitter 105 is remotely disposed away from the receiver 110 and is remotely disposed away from the brake control stage 115. Those skilled in the art will realize that the term “remote” means that a component is physically separated from another component, but at least one of the components is capable of communicating with the other component as will be described in the examples below. The receiver 110 is connectable to a bicycle part such as, for example and without limitations, a bicycle brake 120. The bicycle brake 120 can be used in any manually-powered bicycle which is manufactured and is commercially-available in various forms such as, for example and without limitations, two-wheeled bicycles, tricycles for children, three-wheeled manually-powered bicycles, double-seated bicycles, sport racing bicycles, manually-powered dirt bicycles, or/and other embodiments of bicycles. The bicycle rider uses a pivotally-operated lever 126 that is typically coupled to the bicycle handle-bar 127 and that can pivot in the dual direction 128, in order to move the brake pads into contact with the bicycle wheel so that the brake 120 can apply a braking force on the wheel and decrease the speed of the moving bicycle or stop the moving bicycle.

The brake 120 includes a first arm 125a and a second arm 125b that is behind (and coupled with) the first arm 125a. The arms 125a and 125b are connected together by a pivot pin 130. The pivot pin 130 is typically mounted on a frame member that is part of the frame of a bicycle. A spring (not shown in FIG. 1) may be used between the arms 125a/125b in order to exert a continuous bias for separating the arms 125a/125b from each other. The first arm 125a includes a brake pad mount 135a that mounts a first brake pad 140a, while the second arm 125b includes a brake pad mount 135b that mounts a second brake pad 140b. The details of the brake pad mounts 135a/135b and of the brake pads 140a/140b are well known to those skilled in the art. The extension 145a (of arm 125a) is connected by a connector 148 to a brake wire 150, while the extension 145b (of arm 125b) is connected to a fastener 155.

A pulling motion on the wire 150 (along the direction 152) will cause the extensions 145a and 145b to pivot toward each other. The user can pivot the lever 126 in order to actuate the pulling motion on the wire 150. When the extensions 145a and 145b pivot toward each other, the brake pad 140a will move in the direction 160a toward a bicycle wheel/rim 165 (i.e., wheel and rim assembly 165), and the brake pad 140b will move in the direction 160b toward the bicycle wheel/rim 165. When the brake pads 140a/140b are pressed against the wheel/rim 165, the braking force of the braking pads 140a/140b will stop the wheel/rim 165 rotation if the pulling force on the wire 150 is relatively strong and the braking pads 140a/140b are relatively firmly pressed against the wheel/rim 165. The wheel/rim 165 is formed by a rim portion 166 and a rubber tire 167 that surrounds the rim portion 166. Conventional bicycle tire rim portions are commercially available in various shapes and various circular configurations. Therefore, the rim portion 166 in FIG. 1 is only one non-limiting example of a rim portion shape. When the pulling force on the wire 150 closes the braking pads 140a/140b, the braking pads 140a/140b will come into contact with (and apply the braking force on) the rim portion 166. The braking force of the braking pads 140a/140b will decrease the wheel/rim 165 rotation speed if the pulling force on the wire 150 is relatively less stronger and the braking pads 140a/140b are relatively less firmly pressed against the wheel/rim 165. Typically, the brake 120 applies a substantially equal braking force via the brake pads 140a and 140b on opposing sides of the wheel/rim 165. For purposes on focusing the discussion herein on the features in the embodiments of the invention, other details that are known to those skilled in the art are not discussed further for a bicycle brake. Bicycle brakes are well known to those skilled in the art and are disclosed in further details in, for example, U.S. Pat. Nos. 4,470,483 and 4,553,641.

The transmitter 105 can be, for example and without limitations, a hand-held device or another type of portable device. As an example, the transmitter 105 can be removably coupled to a key ring 175. Two components that are removably coupled (or removably attached or removably secured or removably inserted) means that the two different components can be attached together and detached apart. A key 180 can also be removably coupled to the key ring 175.

The receiver 110 can be removably coupled to the bolt 130 (or can be removably coupled to another suitable part of the bicycle). The receiver 110 is attached to the brake control stage 115, and the brake control stage 115 is connected to the brake wire 150 and applies a pulling force to the wire 150 in response to a control signal 107. The user can push an actuator (e.g., a button) in the transmitter 105 in order to remotely close the brake 120 and to remotely control the braking force by the brake 120 against the wheel/rim 165. A slidable actuator 305 applies the pulling force on the wire 150 along the direction 152. The slidable actuator 305 is disposed in a housing 350 and will be discussed further below.

In one embodiment of the invention, the remote brake system 100 includes a brake control stage 115 and a receiver 110 to be removably coupled with an existing brake 120 of a bicycle. In another embodiment of the invention, the remote brake system 100 includes a receiver 110, a brake control stage 115, and a brake 120, where the receiver 110 (with the brake control stage 115) and brake 120 are installed in a bicycle by the user.

In accordance with an embodiment of the invention, the user can press an actuator (e.g., button) on the transmitter 105 to transmit a control signal 107 that is received by the receiver 110 along the antenna 182. In another embodiment of the invention, the antenna 182 is a built-in antenna or is disposed within a housing of the receiver 110. In response to the receiver 110 having received the control signal 107, the control signal 107 will trigger the brake control stage 115 to actuate an action. For example, based on a value of the control signal 107, the brake control stage 115 is actuated to apply a strong pulling force on the wire 150 so that the pulling force on the wire 150 is relatively strong, the braking pads 140a/140b are relatively firmly pressed against the wheel/rim 165, and the wheel/rim 165 rotation stops. As discussed above, the braking pads 140a applies the braking force by coming into contact with the rim portion 166. Therefore, the user of the transmitter 105 is able to remotely stop the movement of the bicycle by use of the receiver 110.

As another example, based on a value of the control signal 107, the brake control stage 115 is actuated to apply a less stronger pulling force on the wire 150, and this less stronger pulling force causes the braking pads 140a/140b to be relatively less firmly pressed against the wheel/rim 165 and causes a decrease in the rotation speed of the wheel/rim 165. Therefore, the user of the transmitter 105 is able to remotely slow down the movement of the bicycle by use of the receiver 110.

As another example, based on a value of the control signal 107, the brake control stage 115 is actuated to apply no pulling force on the wire 150, and this lack of a pulling force causes the braking pads 140a/140b to move away from the wheel/rim 165 and causes the braking force to be removed from the wheel/rim 165. Specifically, the braking pads 140a/140b will terminate their contact with the rim portion 166 (and, therefore, the braking pads 140a/140b will terminate their braking force on the rim portion 166) when there is no pulling force on the wire 150. Therefore, the user of the transmitter 105 is able to remotely allow the movement to resume for the bicycle by use of the receiver 110.

In another embodiment of the invention, when a control signal 107 is received by the receiver 110, the receiver 110 generates an audio signal 185 and, subsequently, the control signal 107 will cause the brake control stage 115 to pull the wire 150 so that the brake 120 will apply a braking force on the wheel/rim 165. The rider of the bicycle will receive an audible alert (e.g., a beep sound) before the brake control stage 115 pulls the wire 150 and causes the brake 120 to apply a braking force on the wheel/rim 165. Therefore, a child who is riding the bicycle is notified that the bicycle is about to slow down or stop before the brake 120 applies the braking force on the wheel/rim 165.

An embodiment of the remote safety brake system 100 advantageously increases the safety and protection of children who are riding bicycles. For example, the user of the transmitter 105 can remotely stop the bicycle or can remotely decrease the speed of the bicycle. This remote capability advantageously allows the parent to remotely prevent the child from riding the bicycle at a far distance from the parent's physical location and to also remotely stop or remotely slow down the bicycle so that the bicycle does not collide with another object that is moving (e.g., a person, another bicycle, or a moving car) or is stationary (e.g., a tree, a wall, or a parked car). The parent can use the transmitter 105 to remotely stop the bicycle if, for example, there is an emergency, to remotely slow down (yield) the bicycle if, for example, the road is down-hill or if the child is riding the bicycle at a higher speed, and to remotely allow the bicycle to resume movement.

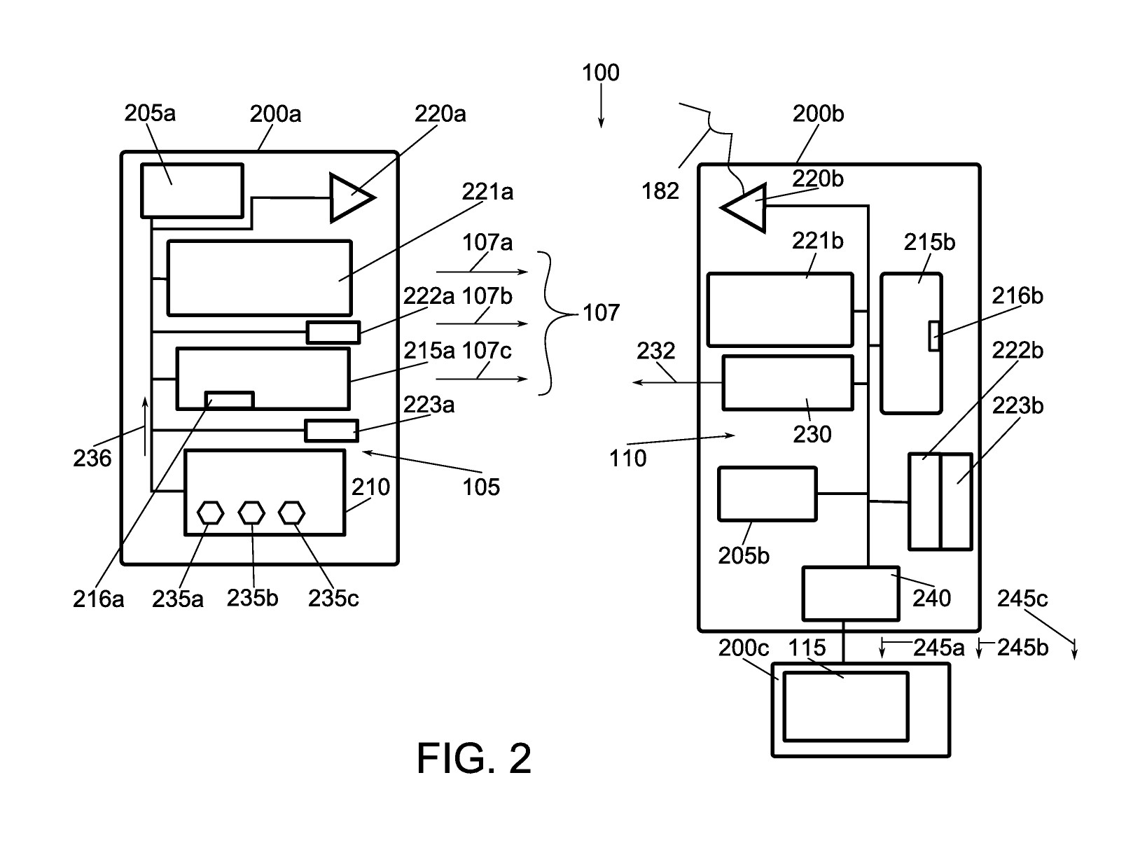

FIG. 2 is a block diagram showing additional details of the apparatus 100 of FIG. 1, in accordance with an embodiment of the invention. When the individual selects (e.g., presses) an actuator (e.g., a button, touch-screen actuator, voice-controlled actuator, or another type of actuating mechanism) in the transmitter 105, the transmitter 105a will transmit a control signal 107 that is received by the antenna 182 in the receiver 110. The control signal 107 can be, for example and without limitations, a radio frequency signal or other types of communication signals such as optical signals, laser signals, infrared signals, ultrasonic signals, ultraviolet signals, low frequency type communication signals, or other suitable communication signals.

The details of the components and circuitries of the transmitter 105, receiver 110, and brake control stage 115 are discussed further below, in accordance with various embodiment of the invention.

The components and circuitries in the transmitter 105, receiver 110, and brake control stage 115 are provided by the baseline technologies 200a, 200b, and 200c, respectively. The baseline technologies are, for example and without limitations, circuit boards with components, wirings, traces, semiconductor elements, and/or other electrical/electronic elements, and/or suitable mechanical parts. Alternatively, the baseline technologies can be programmable logic devices (PLDs) such as, for example and without limitations, field programmable gate arrays (FPGAs) or PLDs in combination with other electrical/electronic elements and/or suitable mechanical parts. Alternatively, the baseline technologies can be nano-technology based elements or nano-technology based elements in combination with other electrical/electronic elements and/or suitable mechanical parts, or other suitable technologies that may be developed as knowledge advances. For ease of discussion, known electrical/electronic elements such as, for example, conductors, traces, buffers, relays, switches, transistors, light emitting diodes, light components, and/or other elements are not shown in FIG. 2.

The circuits in the transmitter 105 and receiver 110 are powered by the power sources 205a and 205b, respectively. The power sources 205a and 205b can be, for example and without limitations, low voltage sources such as batteries or other types of voltage source (e.g., solar-based power source). When the individual presses (selects) an actuator (e.g., button) in the input section 210 in the transmitter 110, the input section 210 detects the pressing (or selection) of the actuator and sends a control signal 236 to the controller 215a to indicate the pressing of the actuator. In response to the control signal 236 from the input stage 210, the controller 215a will trigger the transmitter component (of the transceiver 220a) to transmit the control signal 107 to the receiver 110. In another embodiment of the invention, the component 220a is embodied as a transmitter component 220a instead of as a transceiver. The modulation circuit 221a can modulate the control signal 107 so that the control signal 107 is transmitted to the receiver 110 along a carrier wave, and the demodulation circuit 221b in the receiver 110 can demodulate the control signal 107 from the carrier wave so that the controller 215b can process the control signal 107. The analog-to-digital converter 222a and digital-to-analog converter 223a can be included in the transmitter 105 for proper processing and transmission of the control signal 107. The analog-to-digital converter 222b and digital-to-analog converter 223b can be included in the receiver 110 for proper reception and processing of the control signal 107.

The control signal 107 can be, for example and without limitations, a code of a certain bit size (e.g., 40 bits or less). Controllers and transceivers (and transmitter and receiver components) are commercially available from various vendors. The controller 215a can store the code bits in a memory 216a which can be integrated with the controller 215a or can be a separate memory that is accessible to the controller 215a. Similarly, the controller 215b has access to a memory 216b.

The receiver component of the transceiver 220b (in the receiver 110) receives the control signal 107 via the antenna 182. In another embodiment of the invention, the component 220b is embodied as a receiver component 220b instead of as a transceiver. The controller 215b processes the received control signal 107. In one embodiment of the invention, in response to the received control signal 107, the controller 215b will actuate the audio output stage 230 so that the stage 230 will output an audio signal 232 (e.g., a beep or another audible sound) that the child will hear as she/he is riding on the bicycle and before the brake 120 (FIG. 1) applies the braking pressure on the wheel/rim 165. The audio signal 232 is alternatively shown as audio signal 185 in FIG. 1. In another embodiment of the invention, the audio output stage 230 is omitted from the receiver 110.

In an embodiment of the invention, the input section 210 can include one or more of the following actuators 235a, 235b, and 235c, in various combinations. In another embodiment of the invention, the input section 210 includes only the actuator 235a. In yet another embodiment of the invention, the input section 210 includes only the actuator 235b. In yet another embodiment of the invention, the input section includes only the actuators 235a and 235b. It is noted that there are other embodiments of the invention where the input section 210 includes various combinations that contain one or more of the actuators 235a, 235b, and 235c.

In response to the user having selected (e.g., pressed) the actuator 235a (the STOP actuator 235a), the input section 210 generates a control signal 236 with a first value that represents the selected actuator 235a. The controller 215a will process this control signal 236 and generate a corresponding control signal 107a that is transmitted by the transmitter component 220a and received by the receiver component 220b. The controller 215b will process this corresponding signal 107a. Based on this corresponding signal 107a, the actuator driver 240 will generate an actuation signal 245a (STOP actuation signal 245a) that will cause the brake control stage 115 to close the brake 120 (FIG. 1) and cause the brake 120 to apply a relatively strong braking force against the wheel/rim 165 so that the wheel/rim rotation is remotely stopped and the bicycle is remotely stopped, as similarly discussed above. In another embodiment of the invention, a buffer may be placed in series with the actuator driver 240 so that there is a minor time delay between the time that the audio output stage 230 generates the audio signal 232 and reception of the control signals (e.g., signals 107a, 107b, 107c) by the actuator driver 240. This minor time delay will cause the generation of the audio signal 232 to audibly warn the bicycle rider before the brake 120 (FIG. 1) applies the braking force to the wheel/rim 165.

In response to the user having selected (e.g., pressed) the actuator 235b (the YIELD actuator 235b), the input section 210 generates a control signal 236 with a second value that represents the selected actuator 235b. The controller 215a will process this control signal 236 and generate a corresponding control signal 107b that is transmitted by the transmitter component 220a and received by the receiver component 220b. The controller 215b will process this corresponding signal 107b. Based on this corresponding signal 107b, the actuator driver 240 will generate an actuation signal 245b (YIELD actuation signal 245b) that will cause the brake control stage 115 to close the brake 120 (FIG. 1) and cause the brake 120 to apply a moderate (or less stronger) braking force against the wheel/rim 165 so that the wheel/rim rotation is remotely decreased in speed and the bicycle is remotely decreased in speed (or yielded).

In response to the user having selected (e.g., pressed) the actuator 235c (the RELEASE actuator 235c), the input section 210 generates a control signal 236 with a third value that represents the selected actuator 235c. The controller 215a will process this control signal 236 and generate a corresponding control signal 107c that is transmitted by the transmitter component 220a and received by the receiver component 220b. The controller 215b will process this corresponding signal 107c. Based on this corresponding signal 107c, the actuator driver 240 will generate an actuation signal 245c (RELEASE actuation signal 245c) that will cause the brake control stage 115 to stop the pulling force on the wire 150 (FIG. 1), and to then open the brake 120 (FIG. 1) and cause the brake 120 to release the braking pressure on the wheel/rim 165 so that the wheel/rim rotation is again permitted and the user can again put the bicycle into motion.

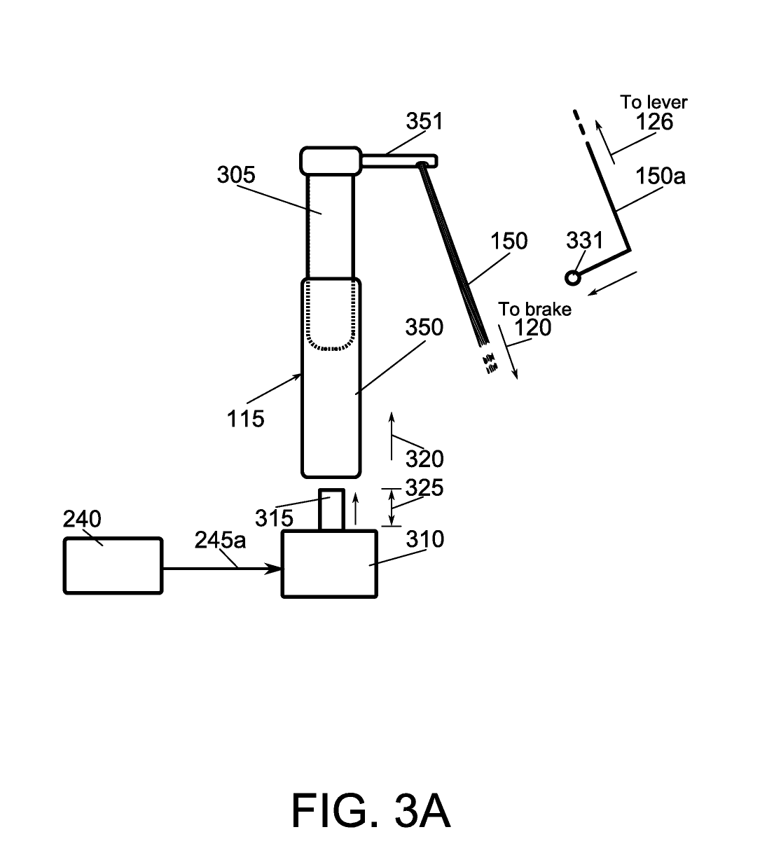

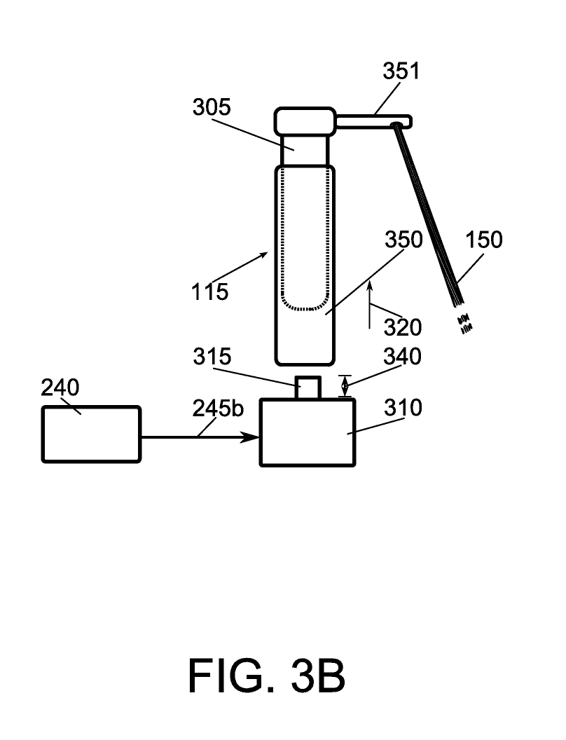

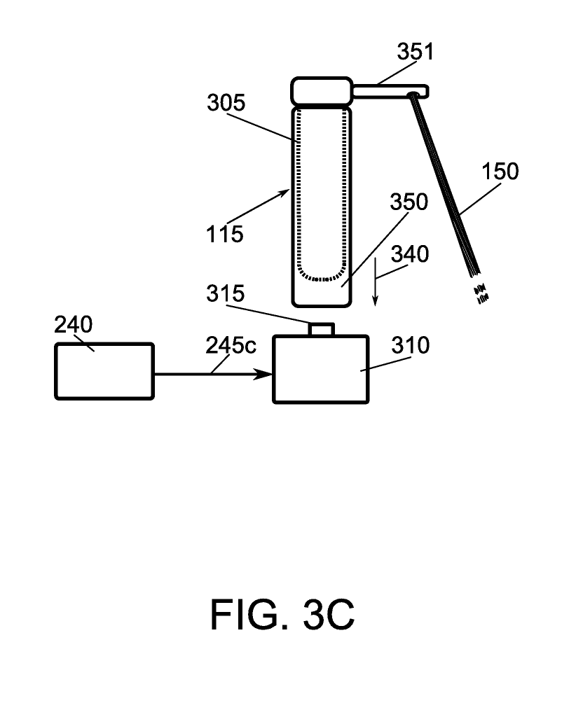

FIGS. 3a, 3b, and 3c are block diagrams of various positions of a slidable actuator 305 in the brake control stage 115, in accordance with an embodiment of the invention. Reference is first made to FIG. 3a. When the actuator driver 240 (in receiver 110) sends the STOP brake control signal 245a into the component 310, the component 310 will push the member 315 against the slidable actuator 305 in the brake control stage 115. The component 310 is typically included within (or coupled to) the housing 350 of the brake control stage 115, but the component 310 is shown in the drawings as external to the housing 350 for purposes of clarity of discussion of the operations of embodiments of the invention. As a result, the actuator 305 will slide upward 320 and the pulling pressure by the actuator 305 on the brake wire 150 will be relatively strong. This relatively strong pulling pressure will cause the brake 120 to apply a relatively strong braking force against the wheel/rim 165 (FIG. 1) so that the wheel/rim rotation is remotely stopped and the bicycle is remotely stopped. In this example, the component 310 extends the member 315 at a maximum distance 325 so that the slidable actuator 305 is extended at a maximum distance along the upward direction 320 and a relatively strong pulling pressure is applied by the actuator 305 on the brake wire 150. In an embodiment of the invention, a member 351 of the slidable actuator 305 is removably attached to the bicycle wire 150. The component 310 can be, for example, a motor or solenoid (or solenoid switch) that can move the member 315 in an upward or downward (axial) direction. The slidable actuator 305 and brake control stage housing 350 can be constructed from rigid material such as, for example and without limitations, stainless steel, rigid metal or alloys, durable plastic, other durable synthetic materials, any suitable durable heavy duty material, or other suitable materials. It is also noted that the slidable actuator 305 can move (slide) upward and downward (or side-to-side), depending on the type of motor or solenoid that is used for the component 310. In both cases, the actuator 305 will apply a pulling force on the brake wire 150 in response to a sliding movement of the actuator 305.

In another embodiment of the invention, where the apparatus 100 will include the brake 120, as commercially sold, the original brake wire 150a will be attached to the bicycle brake lever 126 and will be removably attachable to the brake wire 150 via a conventional attachment mechanism 331.

In FIG. 3b, when the actuator driver 240 (in receiver 110) sends the YIELD brake control signal 245b into the component 310, the component 310 will also push the member 315 against the slidable actuator 305 in the brake control stage 115. As a result, the actuator 305 will slide upward 320 and the pulling pressure by the actuator 305 on the brake wire 150 will be relatively moderate (less stronger). This relatively moderate pulling pressure will cause the brake 120 to apply a relatively moderate (less stronger) brake force against the wheel/rim 165 (FIG. 1) so that the wheel/rim rotation is remotely decreased in speed and the bicycle is remotely decreased in speed (yielded). In this example, the component 310 extends the member 315 at a moderate distance 340 so that the slidable actuator 305 is extended at a moderate distance along the upward direction 320 and a relatively moderate pulling pressure is applied by the actuator 305 on the brake wire 150.

In FIG. 3c, when the actuator driver 240 (in receiver 110) sends the RELEASE brake control signal 245c into the component 310, the component 310 will also retract the member 315 from pressing against the slidable actuator 305 in the brake control stage 115. The member 315 will move in the direction 340 during retraction from the slidable actuator 305. As a result, the actuator 305 will slide downward (along direction 340) and the pulling pressure by the actuator 305 on the brake wire 150 will terminate. This lack of pulling pressure will cause the brake 120 to open and cause the brake 120 to release the braking pressure on the wheel/rim 165 so that the wheel/rim rotation is again permitted and the user can again put the bicycle into motion. In this example, the component 310 does not extend away from the member 315, and therefore, the slidable actuator 305 is freely slidable along the housing 350 of the brake control stage 115 and the member 315 applies no pressure on the slidable actuator 305. The voltage bias of the signals 245a and 245b are opposite of the voltage bias of the signal 245c, so that the member 315 moves in the upward direction 320 in response to the signals 245a or 245b and the member 315 moves in the downward direction 340 in response to the signal 245c.

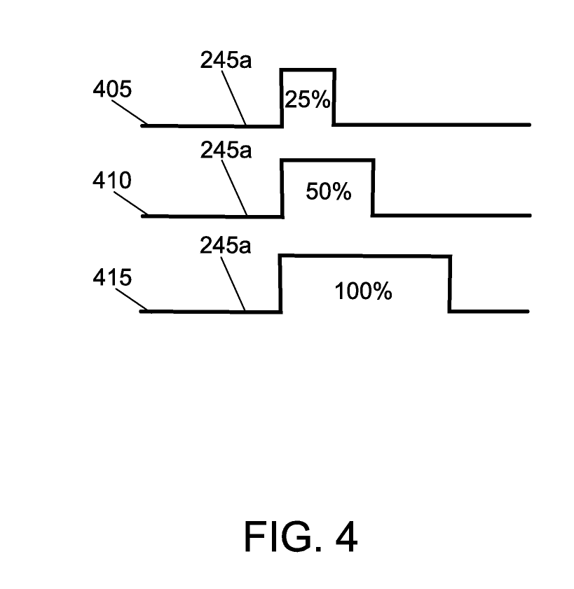

FIG. 4 is a block diagram of signals with different duty cycles that can vary the speed of closing of the brake 120 (FIG. 1), in accordance with an embodiment of the invention. The signals can be, for example, the STOP actuation signal 245a (FIG. 2), the YIELD actuation signal 245b, or the RELEASE actuation signal 245c. In graph 405, the duty cycle of an actuation signal (e.g., signal 245a) is at 25% duty cycle. This lower duty cycle will cause the speed of the closing of the brake arms 125a/125b (FIG. 2) to be relatively slower. In graph 410, the duty cycle of an actuation signal (e.g., signal 245a) is at 50% duty cycle. This medium duty cycle value will cause the speed of the closing of the brake arms 125a/125b to be relatively moderately fast. This medium duty cycle value is achieved when the user presses the buttons (or other actuators) in the transmitter 105 (FIG. 1) at a moderate speed or moderate hand pressure. In graph 410, the duty cycle of an actuation signal (e.g., signal 245a) is at 100% duty cycle. This maximum duty cycle value will cause the speed of the closing of the brake arms 125a/125b to be relatively fast. This maximum duty cycle value is achieved when the user presses the buttons (or other actuators) in the transmitter 105 at a maximum speed or maximum hand pressure. Therefore, when the user increases the hand pressure in the buttons in the transmitter 105, the closing speed of the brake arms 125a/125b is faster, and the bicycle is stopped or yielded at a faster rate.

The actuator stage 240 (FIG. 2) uses pulse width modulation for setting the closing speed of the brake arms 125a/125b based on the different duty cycle values as mentioned above. Pulse width modulation sets the speed that the component 310 (FIGS. 3a and 3b) will slide up the member 315. As known to those skilled in the art, pulse width modulation can be used to control the speed of a motor. Pulse width modulation is commonly used in remote control applications such as, for example, controlling the speed of a remote controlled toy car. The actuator driver 240 will include an electronic speed control (ESC) circuit that can vary the speed of the component 310 (FIGS. 3a, 3b, and 3c) based on duty cycle values as mentioned above. The details of ESC circuits are known to those skilled in the art.

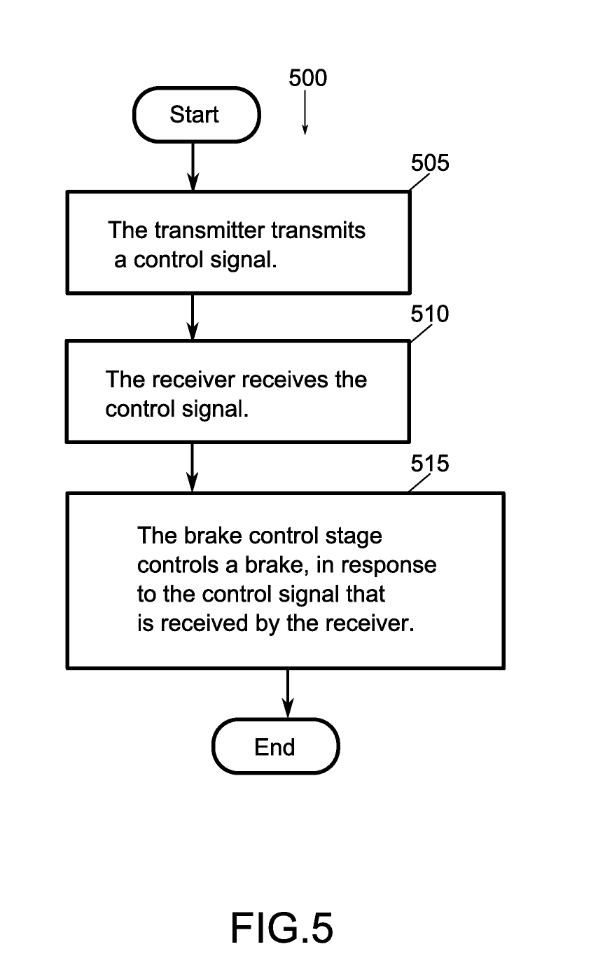

FIG. 5 is a flow diagram of a method 500 in accordance with an embodiment of the invention. In block 505, the transmitter 105 transmits a control signal 107. The transmitter 105 transmits the control signal 107 as a wireless signal. In block 510, the receiver 110 receives the control signal 107. In block 515, the brake control stage 115 controls a brake 120, in response to the control signal 107 that is received by the receiver 110. As discussed above, the brake control stage 115 can control the brake 120, so that the brake 120 applies a relatively strong braking pressure on the wheel/rim 165, applies a relatively moderate (less stronger) braking pressure on the wheel/rim 165, or releases any braking pressure from the wheel/rim 165.

Those skilled in the art will realize that based on the discussion herein, other suitable can be used for the components in the remote safety brake system 100. Those skilled in the art will also realize that based on the discussion herein, other suitable materials or combination of suitable materials can be used for the components in the remote safety brake system 100. Those skilled in the art will also realize, after reading the discussion herein, that the assembly, manufacture, and/or construction of the components of the brake system 100 may be selectively varied based on cost, ease of manufacturing, or/and other considerations. Additionally, the parts or components in the brake system 100 can be suitably varied or substituted with other parts or components, as electrical/electronic components technologies and mechanical technologies improve in the future.

It is also understood that other systems according to an embodiment of the invention can have other forms and can have other different components that are arranged in other ways or in other orientations.

In another embodiment of the invention, a method of assembling a remote safety brake includes: providing a transmitter configured to transmit a control signal, providing a receiver configured to receive the control signal, providing a brake control stage, attaching the brake control stage to the receiver. The brake control stage is responsive to the control signal, and the transmitter is remotely disposed away from the receiver and is remotely disposed away from the brake control stage. The various components in the above method have been previously described above.

Other variations and modifications of the above-described embodiments and methods are possible in light of the teaching discussed herein.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An apparatus comprising:
a remote safety brake comprising:
a transmitter configured to transmit a control signal;
a receiver configured to receive the control signal; and
a brake control stage coupled to the receiver;
wherein the brake control stage is responsive to the control signal, and wherein the transmitter is remotely disposed away from the receiver and is remotely disposed away from the brake control stage.

2. The apparatus of claim 1, wherein the brake control stage is actuated in response to the control signal.

3. The apparatus of claim 1, wherein the brake control stage is configured to actuate a brake of a bicycle, in response to the control signal.

4. The apparatus of claim 1, wherein the brake control stage is configured to actuate a brake in order to stop a bicycle with the brake, in response to the control signal.

5. The apparatus of claim 1, wherein the brake control stage is configured to actuate a brake in order to decrease a speed of a bicycle with the brake, in response to the control signal.

6. The apparatus of claim 1, wherein the brake control stage is configured to actuate a brake in order to permit movement of a bicycle with the brake, in response to the control signal.

7. The apparatus of claim 1, wherein the receiver is connectable to a brake.

8. The apparatus of claim 1, wherein the transmitter is hand-held.

9. The apparatus of claim 1, wherein the transmitter is connectable to a hand-held item.

10. An apparatus comprising:
a remote safety brake comprising:
means for transmitting a control signal;
means for receiving the control signal; and
means for controlling a brake, wherein the controlling means is coupled to the receiving means;
wherein the controlling means is responsive to the control signal, and wherein the transmitting means is remotely disposed away from the receiving means and is remotely disposed away from the controlling means.

11. The apparatus of claim 10, wherein the controlling means is actuated in response to the control signal.

12. The apparatus of claim 10, wherein the controlling means is configured to actuate a brake of a bicycle, in response to the control signal.

13. The apparatus of claim 10, wherein the controlling means is configured to actuate a brake in order to stop a bicycle with the brake, in response to the control signal.

14. The apparatus of claim 10, wherein the controlling means is configured to actuate a brake in order to decrease a speed of a bicycle with the brake, in response to the control signal.

15. The apparatus of claim 10, wherein the controlling means is configured to actuate a brake in order to permit movement of a bicycle with the brake, in response to the control signal.

16. A method comprising:
transmitting a control signal;
receiving the control signal; and
in response to the control signal, controlling a brake.

17. The method of claim 16, wherein controlling the brake comprises actuating the brake in order to stop a bicycle with the brake, in response to the control signal.

18. The method of claim 16, wherein controlling the brake comprises actuating the brake in order to decrease a speed of a bicycle with the brake, in response to the control signal.

19. The method of claim 16, wherein controlling the brake comprises actuating the brake in order to permit movement of a bicycle with the brake, in response to the control signal.

20. A method of assembling a remote safety brake, the method comprising:
providing a transmitter configured to transmit a control signal;
providing a receiver configured to receive the control signal;
providing a brake control stage;
attaching the brake control stage to the receiver;
wherein the brake control stage is responsive to the control signal, and the transmitter is remotely disposed away from the receiver and is remotely disposed away from the brake control stage.
